(19) United States
(12) Patent Application Publication
(10) Pub. No.: US 2025/0331340 A1
(43) Pub. Date: Oct. 23, 2025

(54) LIGHT-EMITTING DEVICE

(71) Applicant: NICHIA CORPORATION, Tokushima (JP)

(72) Inventors: Shinya MITSUHASHI, Tokushima-shi (JP); Yoshiki ENDO, Tokushima-shi (JP)

(73) Assignee: NICHIA CORPORATION, Tokushima (JP)

(21) Appl. No.: 19/186,198

(22) Filed: Apr. 22, 2025

(30) Foreign Application Priority Data
Apr. 23, 2024 (JP) 2024-069996
Oct. 30, 2024 (JP) 2024-190784

(51) Int. Cl. H10H 20/855; H10H 20/85

(52) U.S. Cl. CPC H10H 20/855; H10H 20/8506

(57) ABSTRACT

A light-emitting device includes a base having an upper surface and a recessed portion on a side of the upper surface, a light-emitting element that is disposed in the recessed portion and emits ultraviolet light, a light-transmissive member disposed on the upper surface of the base via a first adhesive member containing no resin, and an optical member disposed on either a region of the upper surface of the base where the light-transmissive member is not disposed or an upper surface of the light-transmissive member via a second adhesive member containing a resin, the optical member including a lens portion and a flange portion. The second adhesive member is located outward of the lens portion in a top view.

### CROSS REFERENCE TO RELATED APPLICATIONS

This application claims priority to Japanese Patent Application No. 2024-69996, filed on Apr. 23, 2024, and Japanese Patent Application No. 2024-190784, filed on Oct. 30, 2024, the entire disclosures of which are hereby incorporated herein by reference.

### BACKGROUND

### Technical Field

The present disclosure relates to a light-emitting device.

### Background Art

For example, Chinese Utility Model No. 218849521 discloses a UVC-LED (Light Emitting Diode) semi-inorganic package structure including a base, a UVC chip disposed on the base, an inorganic lens disposed on the base via an inorganic adhesive, and a dimming lens (optical member) disposed on the inorganic lens (for example, see Chinese Utility Model No. 218849521).

### SUMMARY

An object of certain embodiments of the present disclosure is to reduce deterioration of an adhesive member that bonds an optical member.

A light-emitting device according to an embodiment of the present disclosure includes: a base having an upper surface and a recessed portion on a side of the upper surface; a light-emitting element disposed in the recessed portion and configured to emit ultraviolet light; a light-transmissive member disposed on the upper surface of the base via a first adhesive member containing no resin; and an optical member disposed on either a region of the upper surface of the base where the light-transmissive member is not disposed or an upper surface of the light-transmissive member via a second adhesive member containing a resin, the optical member comprising a lens portion and a flange portion, in which the second adhesive member is located outward of the lens portion in a top view.

A light-emitting device according to an embodiment of the present disclosure includes: a base having an upper surface and a recessed portion on a side of the upper surface; a light-emitting element disposed in the recessed portion and configured to emit ultraviolet light; a light-transmissive member disposed on the upper surface of the base via a first adhesive member containing no resin; and an optical member disposed on an upper surface of the light-transmissive member via a metal adhesive member containing a metal sintered compact, the optical member comprising a lens portion and a flange portion, in which at least a part of the metal adhesive member is located outward of the lens portion in a top view.

An embodiment of the present disclosure can reduce deterioration of an adhesive member that bonds an optical member.

### BRIEF DESCRIPTION OF DRAWINGS

FIG. 1 is a schematic top view illustrating a light-emitting device according to a first embodiment.

FIG. 2 is a schematic cross-sectional view taken along line II-II in FIG. 1.

FIG. 3 is a view illustrating a relationship between a directivity angle and a relative radiation intensity of ultraviolet light emitted from a light-emitting element according to the first embodiment.

FIG. 4 is a schematic top view illustrating a light-emitting device according to a second embodiment.

FIG. 5 is a schematic cross-sectional view taken along line V-V in FIG. 4.

FIG. 6 is a schematic top view illustrating a light-emitting device according to a third embodiment.

FIG. 7 is a schematic cross-sectional view taken along line VII-VII in FIG. 6.

FIG. 8 is a schematic top view illustrating a light-emitting device according to a fourth embodiment.

FIG. 9 is a schematic cross-sectional view taken along line IX-IX in FIG. 8.

FIG. 10 is a schematic cross-sectional view illustrating a light-emitting device according to a first modified example.

FIG. 11 is a schematic cross-sectional view illustrating a light-emitting device according to a second modified example.

FIG. 12 is a schematic top view illustrating a light-emitting device according to a third modified example.

FIG. 13 is a schematic cross-sectional view illustrating a light-emitting device according to a fourth modified example.

FIG. 14 is a schematic top view illustrating an overall configuration of a light-emitting device according to a fifth embodiment.

FIG. 15 is a schematic cross-sectional view taken along line XV-XV in FIG. 14.

FIG. 16 is a schematic top view of a light-transmissive member in the light-emitting device according to the fifth embodiment.

FIG. 17 is a schematic bottom view of the light-transmissive member in the light-emitting device according to the fifth embodiment.

FIG. 18 is a schematic top view of an optical member in the light-emitting device according to the fifth embodiment.

FIG. 19 is a schematic bottom view of the optical member in the light-emitting device according to the fifth embodiment.

### DETAILED DESCRIPTION

Light-emitting devices according to embodiments of the present disclosure are described in detail with reference to the drawings. The following embodiments exemplify light-emitting devices for embodying the technical concept of the present embodiment, and the present embodiment is not limited to the following embodiments. The dimensions, materials, shapes, relative arrangements, and the like of components described in the embodiments are not intended to limit the scope of the present disclosure, but are merely illustrative examples, unless otherwise specifically stated. Note that the sizes, positional relationship, or the like of members illustrated in each of the drawings may be exaggerated for clarity of description. In the following description, members having the same names and reference characters represent the same members or members of the same quality, and a detailed description of these members is omitted as appropriate.

In the following drawings, directions may be indicated by an X axis, a Y axis, and a Z axis. The X axis, the Y axis, and the Z axis are orthogonal to each other. The direction in the X direction in which an arrow points is referred to as a +X direction or a +X side and the opposite direction to the +X direction is referred to as a −X direction or a −X side. The direction in the Y direction in which an arrow points is referred to as a +Y direction or a +Y side and the opposite direction to the +Y direction is referred to as a −Y direction or a −Y side. The direction in the Z direction in which the arrow points is referred to as a +Z direction or a +Z side and the opposite direction to the +Z direction is referred to as a −Z direction or a −Z side.

In the following description, terms indicating a specific direction or position (for example, “upper”, “lower”, and other terms including those terms) may be used. These terms are merely used to facilitate understanding of relative directions or positions in the referenced drawings. In the following description, “upward” refers to the +Z direction side, and “downward” refers to the −Z direction side. “Disposing” includes not only a case of disposing by direct contact but also a case of indirectly disposing, for example, via another member. A “top view” refers to a view of an object from the +Z direction. An end view illustrating only a cut surface may be used as a cross-sectional view.

### First Embodiment

### Configuration of Light-Emitting Device According to First Embodiment

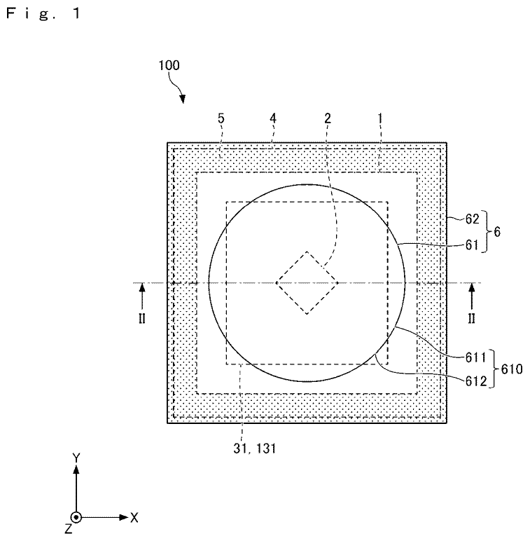

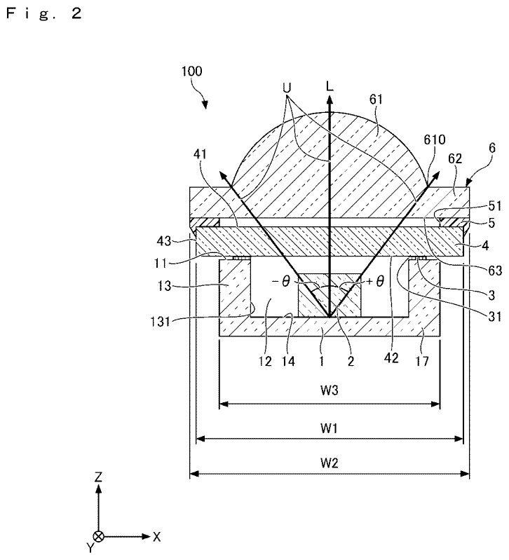

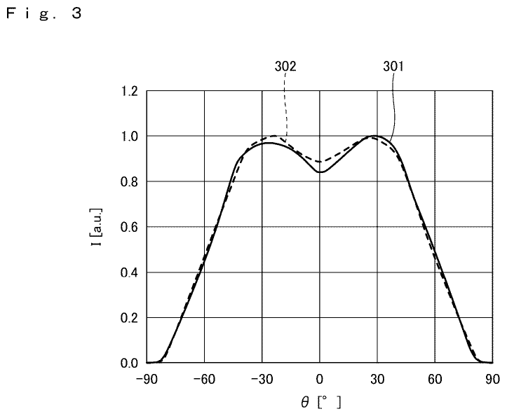

A configuration of a light-emitting device according to a first embodiment is described with reference to FIGS. 1 to 3. FIG. 1 is a schematic top view illustrating a light-emitting device 100 according to a first embodiment. FIG. 2 is a schematic cross-sectional view taken along line II-II in FIG. 1. FIG. 3 is a diagram illustrating a relationship between a directivity angle θ and a relative radiation intensity I of ultraviolet light U emitted from a light-emitting element 2 according to the first embodiment. In the example illustrated in FIG. 1, hatching is applied to a second adhesive member 5 in order to easily distinguish members. In the example illustrated in FIG. 2, a part of the ultraviolet light U emitted from the light-emitting element 2 is indicated by an arrow.

The light-emitting device 100 includes a base 1 having an upper surface 11 and a recessed portion 12 on the upper surface 11 side, the light-emitting element 2 that is disposed in the recessed portion 12 and emits ultraviolet light, and a light-transmissive member 4 disposed on the upper surface 11 of the base 1 via a first adhesive member 3 including no resin. The light-emitting device 100 further includes an optical member 6 that is disposed on an upper surface 41 of the light-transmissive member 4 via the second adhesive member 5 including a resin and includes a lens portion 61 and a flange portion 62. The second adhesive member 5 is located outward of the lens portion 61 in a top view.

The light-emitting device 100 emits the ultraviolet light U from the light-emitting element 2. The ultraviolet light U emitted upward from the light-emitting element is emitted to the outside by passing through the light-transmissive member 4 and the optical member 6. In the light-emitting device 100, the ultraviolet light U irradiated onto the second adhesive member 5 can be reduced. Thus, deterioration of the second adhesive member 5 can be reduced. By reducing the deterioration of the second adhesive member 5, a decrease in the adhesive strength of the second adhesive member 5 that bonds the light-transmissive member 4 and the optical member 6 can be inhibited. In addition, by inhibiting the deterioration of the second adhesive member 5, discoloration of the second adhesive member 5 can be reduced. When the second adhesive member 5 is discolored, the second adhesive member 5 may absorb the ultraviolet light U. In the light-emitting device 100, even if the second adhesive member 5 is discolored, the ultraviolet light U traveling from the light-emitting element 2 to the lens portion 61 is less likely to be absorbed by the discolored second adhesive member 5 because the second adhesive member 5 is located outward of the lens portion 61. As a result, a decrease in the light extraction efficiency of the ultraviolet light U emitted from the lens portion 61 to the outside can be inhibited.

In the light-emitting device 100, as illustrated in FIG. 2, each of a width W1 of the light-transmissive member 4 and a width W2 of the optical member 6 is wider than a width W3 of the base 1 in cross-sectional view, respectively. Thus, when the second adhesive member 5 is disposed on the outer end portion side of the upper surface 41 of the light-transmissive member 4, a part of the ultraviolet light U traveling toward the second adhesive member 5 can be shielded by an inner surface 131 defining the recessed portion in the base 1. Therefore, the ultraviolet light U irradiated onto the second adhesive member 5 can be reduced, so that the deterioration of the second adhesive member 5 can be reduced. The “width of the light-transmissive member 4” refers to a distance in the X direction from an outer end portion on the −X side to an outer end portion on the +X side on a lower surface 42 of the light-transmissive member 4 in FIG. 2. The “width of the optical member 6” refers to a distance in the X direction from an outer end portion on the −X side to an outer end portion on the +X side on a lower surface 63 of the optical member 6 in FIG. 2. The “width of the base 1” refers to a distance in the X direction from an outer end portion on the −X side of the upper surface 11 of a sidewall portion 13, located on the −X side, of two sidewall portions 13 of the base 1 to an outer end portion on the +X side of the upper surface 11 of a sidewall portion 13, located on the +X side, of the two sidewall portions 13 of the base 1 in FIG. 2.

In the light-emitting device 100, the width W1 of the light-transmissive member 4 is narrower than the width W2 of the optical member 6 in a cross-sectional view. The second adhesive member 5 is disposed in a region including the outer end portion of the lower surface of the optical member 6 and is disposed on a part of a lateral surface of the light-transmissive member 4. Thus, the adhesive strength of the second adhesive member 5 that bonds the light-transmissive member 4 and the optical member 6 can be increased.

The second adhesive member 5 is not limited to being disposed in the region including the outer end portion of the lower surface of the optical member 6, and may be spaced apart from the outer end portion of the lower surface of the optical member 6. The second adhesive member 5 is not limited to being disposed on a part of at least one lateral surface 43 of the light-transmissive member 4, and may be disposed on the entirety of lateral surfaces 43 of the light-transmissive member 4 or may not be disposed on the lateral surfaces of the light-transmissive member 4.

In a top view, the outer shape of each of the base 1, the light-transmissive member 4, and the optical member 6 is rectangular in the example illustrated in FIG. 1. Note that a rectangle is a shape including four sides and four corners. However, the outer shape of at least one of the base 1, the light-transmissive member 4, and the optical member 6 may be substantially rectangular. The substantially rectangular shape means a shape such as a shape in which a part of a corner of a rectangle is removed and a shape in which a corner of a rectangle is rounded, in addition to the rectangular shape. In a top view, the outer shape of at least one of the base 1, the light-transmissive member 4, and the optical member 6 is not limited to a rectangular shape or a substantially rectangular shape, and may be a substantially circular shape, a substantially elliptical shape, a substantially polygonal shape, or the like.

Each component constituting the light-emitting device 100 is described below in detail.

### Base 1

The base 1 is a member for disposing the light-emitting element 2. The base 1 includes a base portion 17 and a sidewall portion 13 located on the base portion 17. The base 1 includes the upper surface 11 and the recessed portion 12 provided on the upper surface 11 side. The upper surface 11 of the base 1 is an upper surface of the sidewall portion 13. The recessed portion 12 is defined by the inner surface 131 of the sidewall portion 13 and a bottom surface 14. The bottom surface 14 is the bottom of the recessed portion 12 and corresponds to an upper surface of the base portion 17. A space in the recessed portion 12 is defined by the inner surface 131 of the sidewall portion 13, the bottom surface 14, and the lower surface 42 of the light-transmissive member 4. In the example illustrated in FIG. 1, the sidewall portion 13 annularly surrounds the light-emitting element 2. The shape of the upper surface 11 of the base 1 in a top view is a rectangular annular shape.

The base portion 17 and the sidewall portion 13 of the base 1 are each made using an insulating material and include, for example, ceramic. The ceramic preferably has high heat resistance and high weather resistance. Aluminum nitride, aluminum oxide, mullite, or the like can be used as the ceramic. In the example illustrated in FIG. 2, the base portion 17 and the sidewall portion 13 are integrally made of the same material. However, the present disclosure is not limited thereto, and the base portion 17 and the sidewall portion 13 may be made of different materials as separate bodies.

The base 1 includes a wiring. The wiring includes, for example, an upper surface wiring disposed on the bottom surface 14 of the recessed portion 12 (that is, the upper surface of the base portion 17) and electrically connected to the light-emitting element 2, a lower surface wiring disposed on the lower surface of the base portion 17, and a relay wiring electrically connecting the upper surface wiring and the lower surface wiring.

### Light-Emitting Element 2

The light-emitting element 2 is disposed on the bottom surface 14 of the recessed portion 12. A peak wavelength of the ultraviolet light U emitted by the light-emitting element 2 is, for example, in a range from 200 nm to 410 nm. An LED can be used as the light-emitting element 2. In the example illustrated in FIGS. 1 and 2, the number of light-emitting elements 2 included in the light-emitting device 100 is one. However, the number of light-emitting elements 2 included in the light-emitting device 100 is not limited to one, and may be plural.

In a top view, an outer shape of the light-emitting element 2 is, for example, rectangular. When the outer shape of the light-emitting element 2 is rectangular, the light-emitting element 2 is preferably disposed such that the bisector of an angle with respect to an apex of the light-emitting element 2 and the side of the base 1 intersect substantially perpendicularly as illustrated in FIG. 1. Such an arrangement can reduce absorption of the ultraviolet light U emitted from the light-emitting element 2 by the inner surface 131 of the base 1. However, the light-emitting element 2 may be disposed such that the side of the light-emitting element 2 is substantially parallel to the side of the base 1.

### First Adhesive Member 3

The first adhesive member 3 is a member for bonding the base 1 and the light-transmissive member 4. The first adhesive member 3 is disposed on the upper surface 11 of the base 1. The first adhesive member 3 is made of a material including no resin. Therefore, even though the first adhesive member 3 is irradiated with the ultraviolet light U emitted from the light-emitting element, the first adhesive member 3 is less likely to deteriorate. As the first adhesive member 3, for example, a solder alloy such as gold-tin, or a metal material such as a brazing material can be used. When the first adhesive member 3 is formed based on a metal material, for example, a first metal film is provided on the base 1, a second metal film is provided on the light-transmissive member 4, and the first metal film and the second metal film are bonded to each other by the first adhesive member 3, so that the base 1 and the light-transmissive member 4 can be bonded to each other via the first adhesive member 3. The first adhesive member 3 is disposed around the entire periphery of the upper surface 11 having a rectangular annular shape in a top view and is bonded to the upper surface 11, so that the space in the recessed portion 12 can be made airtight. Thus, deterioration of the light-emitting element 2 can be reduced.

### Light-Transmissive Member 4

The light-transmissive member 4 is a member having light transmissivity that transmits at least the ultraviolet light U emitted from the light-emitting element 2. The light-transmissive member 4 transmits 60% or more, preferably 90% or more of the ultraviolet light U emitted from the light-emitting element 2.

The light-transmissive member 4 is disposed on the base 1 so as to cover the upper side of the space in the recessed portion 12 in which the light-emitting element 2 is disposed. By covering the upper side of the space in the recessed portion 12 with the light-transmissive member 4, the light-emitting element 2 can be protected from moisture, organic matter, and the like included in the outside air.

As the material constituting the light-transmissive member 4, for example, a material having a small difference in linear expansion coefficient from the material constituting the base portion 17 and the sidewall portion 13 of the base 1 can be used. Even though the base portion 17 and the sidewall portion 13 of the base 1 and the light-transmissive member 4 expand due to a change in the temperature of the light-emitting device 100, a stress load corresponding to a difference in linear expansion coefficient between the base portion 17 and the sidewall portion 13 of the base 1 and the light-transmissive member 4 and a decrease in the adhesive strength of the first adhesive member 3 that bonds the sidewall portion 13 of the base 1 and the light-transmissive member 4 can be inhibited. When aluminum nitride is used as the material constituting the base portion 17 and the sidewall portion 13 of the base 1, sapphire can be used as the material constituting the light-transmissive member 4. However, the material constituting the light-transmissive member 4 is not limited to sapphire, and glass or the like can be used.

### Second Adhesive Member 5

The second adhesive member 5 is a member for bonding the optical member 6. In the present embodiment, the second adhesive member 5 is a member for bonding the optical member 6 and the light-transmissive member 4. The second adhesive member 5 includes a resin material such as a silicone resin. Since the second adhesive member 5 includes a resin, the second adhesive member 5 may deteriorate when irradiated with the ultraviolet light U from the light-emitting element 2. As described above, since the second adhesive member 5 is disposed outside the lens portion 61 in a top view, the ultraviolet light U with which the second adhesive member 5 is irradiated can be reduced and the deterioration of the second adhesive member 5 can be reduced.

As illustrated in FIG. 2, an inner end portion 51 of the second adhesive member 5 is preferably located on the outer side of an inner end portion 31 of the first adhesive member 3. Thus, a part of the ultraviolet light U emitted from the light-emitting element 2 and traveling in the direction in which the second adhesive member 5 is located can be blocked by the first adhesive member 3 and the inner surface 131 of the sidewall portion 13. As a result, the ultraviolet light U with which the second adhesive member 5 is irradiated can be reduced, and the deterioration of the second adhesive member 5 can be reduced.

### Optical Member 6

The optical member 6 is a member for controlling light distribution characteristics. The optical member 6 is disposed on the light-transmissive member 4. The optical member 6 transmits the ultraviolet light U emitted from the light-emitting element 2. The optical member 6 transmits the ultraviolet light U from the light-emitting element 2 and can converge or diverge the ultraviolet light U and cause it to exit. The optical member 6 may include a glass material such as borosilicate glass or quartz glass.

In the example illustrated in FIG. 2, the optical member 6 is a plano-convex lens including a flat lower surface 63 facing the light-transmissive member 4 and a convex surface on the side opposite to the lower surface 63 facing the light-transmissive member 4. However, the optical member 6 may be a plano-concave lens including an upward concave surface on the side opposite to the lower surface 63 facing the light-transmissive member 4. The optical member 6 may also be a lens array including a plurality of convex surfaces or concave surfaces on the side opposite to the lower surface 63 facing the light-transmissive member 4. Moreover, the optical member 6 may be a Fresnel lens, a diffraction lens, or the like. When the light-emitting device 100 includes a plurality of light-emitting elements 2, the optical member 6 may include a plurality of lens portions 61 corresponding to the plurality of light-emitting elements 2, or may include one lens portion 61 in which each of the plurality of light-emitting elements 2 is disposed in a top view.

In a top view, the flange portion 62 is located outside the lens portion 61. The flange portion 62 is annularly disposed outside the lens portion 61. In the example illustrated in FIG. 1, the shape of the outer end portions of an upper surface and a lower surface of the flange portion 62 is a rectangular shape, and the shape of the inner end portion of the upper surface of the flange portion 62 (that is, the shape of an outer end portion 610 of the lens portion) is a circular shape. In the example illustrated in FIG. 1, the flange portion 62 includes four corners. The flange portion 62 is a portion to which the second adhesive member 5 is bonded when the optical member 6 is bonded to the light-transmissive member 4 by the second adhesive member 5. In the example illustrated in FIG. 1, the second adhesive member 5 is disposed on the outer end portion side of the lower surface of the flange portion 62 and is continuously disposed around the entire periphery of the annular flange portion 62 in a top view. The shape of the second adhesive member 5 in a top view is, for example, a rectangular annular shape.

The lens portion 61 is a portion having a lens surface and implementing a lens function. In the example illustrated in FIG. 1, a portion 611 of the outer end portion 610 of the lens portion 61 located on the side of a region between adjacent corners of the flange portion 62 overlaps the upper surface 11 of the base 1 in a top view. In a top view, a portion 612 of the outer end portion 610 of the lens portion 61 located on the side of a region of the corner of the flange portion 62 also overlaps the recessed portion 12 of the base 1. That is, in a top view, a part of the outer end portion 610 of the lens portion 61 overlaps the upper surface 11, and the remaining part thereof overlaps the recessed portion 12. In top view, a part of the outer end portion 610 of the lens portion 61 is not necessarily overlap the upper surface 11 and the remaining part thereof need not necessarily overlap the recessed portion 12. Alternatively, the entire outer end portion 610 of the lens portion 61 may overlap the upper surface 11. When a part of the outer end portion 610 of the lens portion 61 overlaps the upper surface 11 and the remaining part thereof overlaps the recessed portion 12 in a top view, even though the thickness of the lens portion 61 is reduced as compared with when the entire outer end portion 610 of the lens portion 61 overlaps the upper surface 11, optical characteristics of narrow light distribution similar to that when the entire outer end portion 610 of the lens portion 61 overlaps the upper surface 11 can be obtained. Therefore, the light-emitting device can be downsized. On the other hand, when the entire outer end portion 610 of the lens portion 61 overlaps the upper surface 11 in a top view, a large amount of the ultraviolet light U from the light-emitting element 2 can be taken in and the light extraction efficiency can be increased as compared with when a part of the outer end portion 610 of the lens portion 61 overlaps the upper surface 11 and the remaining part thereof overlaps the recessed portion 12.

A light-reflective member can be disposed on the bottom surface 14 of the base so as to be in contact with the inner surface 131 of the base 1. The light-reflective member can surround the light-emitting element 2. The light-reflective member is made of, for example, an inorganic material including boron nitride or alkali metal silicate. Moreover, the light-reflective member can further include titanium oxide or zirconium oxide. The light-reflective member can include an inclined region where the height from the bottom surface 14 decreases from the inner surface 131 toward the light-emitting element 2. The inclined region is continuously disposed on the inner surface 131 and the bottom surface 14 of the base 1. Since the light-reflective member includes the inclined region, the ultraviolet light U emitted from the light-emitting element 2 and traveling to the light-reflective member can be reflected upward. As a result, the light extraction efficiency of the light-emitting device 100 can be improved.

In FIG. 3, a graph 301 indicated by a solid line represents a relationship between the directivity angle θ in the X direction and the relative radiation intensity I of the ultraviolet light U emitted from the light-emitting device 100. A graph 302 indicated by a broken line represents a relationship between the directivity angle θ in the Y direction and the relative radiation intensity I of the ultraviolet light U emitted from the light-emitting device 100. As illustrated in FIG. 2, the directivity angle θ refers to an angle θ representing the spread of light emitted from the light-emitting element 2 with respect to an optical axis L. Regarding the directivity angle θ, an angle inclined in the +X direction with respect to the optical axis L is represented by +θ°, and an angle inclined in the −X direction with respect to the optical axis L is represented by −θ°. In the example illustrated in FIG. 3, in both the graph 301 and the graph 302, the relative radiation intensity is high when the directivity angle θ is approximately=30°. Therefore, the second adhesive member 5 disposed between the optical member 6 and the light-transmissive member 4 is preferably disposed outside the position through which the ultraviolet light U emitted from the light-emitting element 2 and having a directivity angle θ of approximately ±30° passes, in a top view. The directivity angle θ of the ultraviolet light U passing through the outer end portion 610 of the lens portion 61 illustrated in FIG. 2 is, for example, ±40°. Such an arrangement can reduce irradiation of the second adhesive member 5 with a portion having a higher relative radiation intensity of the ultraviolet light U emitted from the light-emitting element 2 and thus reduce the deterioration of the second adhesive member 5.

### Method of Manufacturing Light-Emitting Device 100

The method of manufacturing the light-emitting device 100 includes, for example, a step (S10) of disposing the light-emitting element 2 on the base 1, a step (S11) of disposing the light-transmissive member 4 on the upper surface 11 of the base 1 via the first adhesive member 3, a step (S12) of disposing the second adhesive member 5 on the upper surface 41 of the light-transmissive member 4 and/or the lower surface 63 of the optical member 6, and a step (S13) of disposing the optical member 6 on the upper surface 41 of the light-transmissive member 4 via the second adhesive member 5. The order of S11 to S13 may be as follows: S11, S12, and S13, or S12, S13, and S11.

### Second Embodiment

### Configuration of Light-Emitting Device According to Second Embodiment

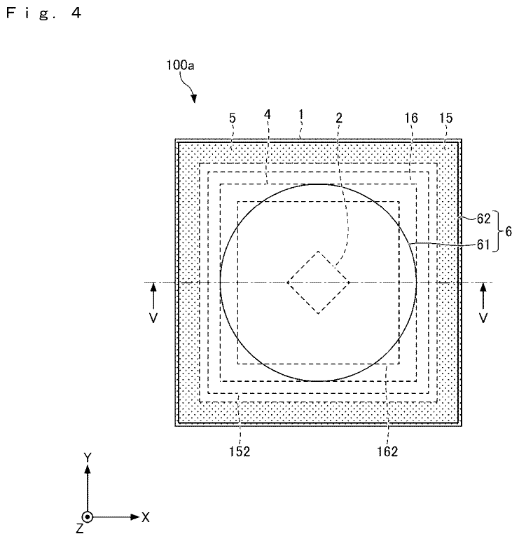

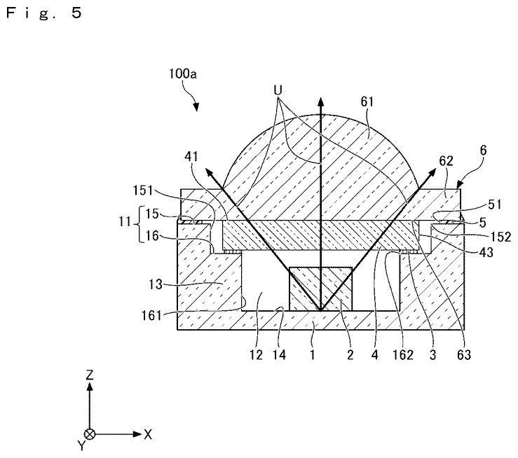

A configuration of a light-emitting device according to a second embodiment is described with reference to FIGS. 4 and 5. The same names and reference characters as those in the previously described embodiment of the present disclosure indicate the same members or configurations or members or configurations of the same quality, and detailed descriptions thereof are omitted as appropriate. This is also true for each of the following embodiments and modified examples.

FIG. 4 is a schematic top view illustrating a light-emitting device 100a according to the second embodiment. FIG. 5 is a schematic cross-sectional view taken along line V-V in FIG. 4. In the example illustrated in FIG. 4, hatching is applied to the second adhesive member 5 in order to easily distinguish the members. In the example illustrated in FIG. 5, a part of the ultraviolet light U emitted from the light-emitting element 2 is indicated by an arrow.

In the light-emitting device 100a according to the second embodiment, the upper surface 11 of the base 1 includes an outer upper surface 15 and an inner upper surface 16 located inward of the outer upper surface 15 in a top view. The inner upper surface 16 is located below the outer upper surface 15. The light-transmissive member 4 is disposed on the inner upper surface 16 via the first adhesive member 3. The optical member 6 is disposed on the outer upper surface 15 via the second adhesive member 5. The light-emitting device 100a according to the second embodiment is different from the light-emitting device 100 according to the first embodiment mainly in the above points.

As illustrated in FIG. 5, in the light-emitting device 100a, since the second adhesive member 5 is disposed on the outer upper surface 15, the ultraviolet light U with which the second adhesive member 5 is irradiated can be reduced and thus the deterioration of the second adhesive member 5 can be reduced.

As illustrated in FIG. 5, in the light-emitting device 100a, the lateral surface 43 of the light-transmissive member 4 is preferably spaced apart from a lateral surface 151 (hereinafter, also referred to as a “first lateral surface 151”) connecting the outer upper surface 15 and the inner upper surface 16 of the base 1. For example, when the material constituting the base portion 17 and the sidewall portion 13 of the base 1 is aluminum nitride and the material constituting the light-transmissive member 4 is sapphire, the light-transmissive member 4 is more likely to expand than the base portion 17 and the sidewall portion 13 of the base 1 because sapphire has a larger linear expansion coefficient than aluminum nitride. Therefore, even though the light-transmissive member 4 expands due to a change in the temperature of the light-emitting device 100a, the likelihood of contact between the first lateral surface 151 of the base 1 and the lateral surface 43 of the light-transmissive member 4 can be reduced. As a result, stress from the first lateral surface 151 of the base 1 can be prevented from being applied to the lateral surface 43 of the light-transmissive member 4, thereby reducing the likelihood of occurrence of cracking in the light-transmissive member 4 and/or peeling of the light-transmissive member 4 from the base 1.

As illustrated in FIG. 5, in the light-emitting device 100a, the inner end portion 51 of the second adhesive member 5 is preferably located on the outer side of an inner end portion 152 of the outer upper surface 15 of the base 1. In that case, a part of the ultraviolet light U emitted from the light-emitting element 2 and traveling in the direction in which the second adhesive member 5 is located can be blocked by the first lateral surface 151. As a result, the ultraviolet light U with which the second adhesive member 5 is irradiated can be reduced, and the deterioration of the second adhesive member 5 can be reduced. Note that the inner end portion 51 of the second adhesive member 5 is not limited to being located on the outer side of the inner end portion 152 of the outer upper surface 15 of the base 1, and may coincide with the inner end portion 152 of the outer upper surface 15 of the base 1.

In the light-emitting device 100a, the light-transmissive member 4 and the optical member 6 are in contact with each other. Thus, since no gap is present between the light-transmissive member 4 and the optical member 6, total reflection that occurs at the boundary between the light-transmissive member 4 and a gas (for example, air) present in the gap can be reduced. When the amount of the totally reflected ultraviolet light U is reduced, the amount of the ultraviolet light U incident on the optical member 6 through the light-transmissive member 4 is increased, so that the light extraction efficiency of the light-emitting device 100a can be increased. However, the light-transmissive member 4 and the optical member 6 may be spaced apart from each other. When the light-transmissive member 4 and the flange portion 62 are spaced apart from each other, a gap is present between the light-transmissive member 4 and the optical member 6. Therefore, even though the light-transmissive member 4 and the optical member 6 expand due to a change in the temperature of the light-emitting device 100a, the likelihood of contact between the light-transmissive member 4 and the optical member 6 can be reduced. Since the likelihood of contact between the light-transmissive member 4 and the optical member 6 can be reduced, at least one of stress from the light-transmissive member 4 to the optical member 6 and stress from the optical member 6 to the light-transmissive member 4 can be reduced. The same also applies to light-emitting devices 100b, 100c, and 100g to be described below.

In the light-emitting device 100a, the lens portion 61 is located inward of the outer upper surface 15 in a top view. Thus, the likelihood of transmission of the ultraviolet light U traveling from the light-emitting element 2 to the lens portion 61 through the second adhesive member 5 can be reduced. The same also applies to the light-emitting devices 100b to 100g to be described below.

In the example illustrated in FIG. 5, the width of the optical member 6 and the width of the light-transmissive member 4 are narrower than the width of the base 1. The width of the optical member 6 need not be narrower than the width of the base 1, and may be the same as the width of the base 1. The same also applies to the light-emitting devices 100b and 100c to be described below.

### Method of Manufacturing Light-Emitting Device 100a

The method of manufacturing the light-emitting device 100a includes, for example, a step (S10) of disposing the light-emitting element 2 on the base 1, a step (S21) of disposing the light-transmissive member 4 on the inner upper surface 16 of the base 1 via the first adhesive member 3, a step (S22) of disposing the second adhesive member 5 on the outer upper surface 15 of the base 1 and/or the lower surface 63 of the optical member 6, and a step (S23) of disposing the optical member 6 on the outer upper surface 15 of the base 1 via the second adhesive member 5.

### Third Embodiment

### Configuration of Light-Emitting Device According to Third Embodiment

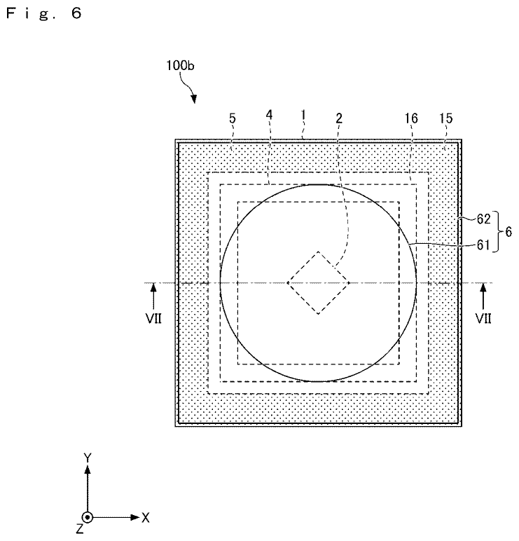

A configuration of a light-emitting device according to a third embodiment is described with reference to FIGS. 6 and 7. FIG. 6 is a schematic top view illustrating a light-emitting device 100b according to the third embodiment. FIG. 7 is a schematic cross-sectional view taken along line VII-VII illustrated in FIG. 6. In the example illustrated in FIG. 6, hatching is applied to the second adhesive member 5 in order to easily distinguish the members. In the example illustrated in FIG. 7, a part of the ultraviolet light U emitted from the light-emitting element 2 is indicated by an arrow.

In the light-emitting device 100b according to the third embodiment, the upper surface 11 of the base 1 includes an outer upper surface 15 and an inner upper surface 16 located inward of the outer upper surface 15 in a top view. The inner upper surface 16 is located above the outer upper surface 15. The light-transmissive member 4 is disposed on the inner upper surface 16 via the first adhesive member 3. The optical member 6 is disposed on the outer upper surface 15 via the second adhesive member 5. The light-emitting device 100b according to the third embodiment is different from the light-emitting device 100 according to the first embodiment mainly in the above points.

In the example illustrated in FIG. 7, the optical member 6 includes a leg portion 64 connected to the flange portion 62, below the flange portion 62. For the optical member 6, a lower surface 641 of the leg portion 64 is disposed on the outer upper surface 15 via the second adhesive member 5. The leg portion 64 may be disposed continuously around the entire periphery of the annular flange portion 62 or may be disposed intermittently in a top view. When the leg portion 64 is intermittently disposed in a top view, for example, respective portions of the leg portion 64 can be disposed at the four corners of the flange portion 62.

In the light-emitting device 100b, the second adhesive member 5 is disposed on the outer upper surface 15, and the inner upper surface 16 is located above the outer upper surface 15. The ultraviolet light U from the light-emitting element 2 is blocked by a second lateral surface 161 connecting the inner upper surface 16 and the bottom surface 14 of the base 1, and thus does not reach the second adhesive member 5. Thus, the light-emitting device 100b can further reduce the ultraviolet light U with which the second adhesive member 5 is irradiated, and thus further reduce the deterioration of the second adhesive member 5, as compared with the light-emitting devices 100 and 100a.

In the light-emitting device 100b, the lateral surface of the light-transmissive member 4 is spaced apart from the lateral surface of the leg portion 64 of the optical member 6. Thus, even though the light-transmissive member 4 expands due to a change in the temperature of the light-emitting device 100b, the likelihood of contact between the leg portion 64 of the optical member 6 and the lateral surface 43 of the light-transmissive member 4 can be reduced. As a result, no stress is generated between the base 1 and the light-transmissive member 4, thereby reducing the likelihood of occurrence of at least one of cracking in the light-transmissive member 4, cracking in the optical member 6, peeling of the first adhesive member 3, and peeling of the second adhesive member 5. In addition, since a gap is present between the lateral surface of the light-transmissive member 4 and the lateral surface of the leg portion 64 of the optical member 6, a part of the ultraviolet light U traveling from the lateral surface of the light-transmissive member 4 to the optical member 6 is totally reflected at the boundary between the lateral surface of the light-transmissive member 4 and a gas (for example, air) present in the gap. This increases the amount of light reaching the lens portion 61 of the optical member 6, thereby increasing the light extraction efficiency of the light-emitting device 100b. However, the present disclosure is not limited thereto, and the lateral surface of the light-transmissive member 4 may be in contact with the lateral surface of the leg portion 64 of the optical member 6.

In the light-emitting device 100b, the lateral surface of the leg portion 64 of the optical member 6 is in contact with the first lateral surface 151 of the base 1. Thus, it is easy to perform alignment with the optical member 6. However, the lateral surface of the leg portion 64 of the optical member 6 may be spaced apart from the first lateral surface 151 of the base 1.

In the light-emitting device 100b, the second adhesive member 5 is disposed on the outer upper surface 15 of the base 1 and is further in contact with the first lateral surface 151. This makes it possible to improve the adhesion between the second adhesive member 5 and the base 1.

### Method of Manufacturing Light-Emitting Device 100b

The method of manufacturing the light-emitting device 100b includes, for example, a step (S10) of disposing the light-emitting element 2 on the base 1, a step (S31) of disposing the light-transmissive member 4 on the inner upper surface 16 of the base 1 via the first adhesive member 3, a step (S32) of disposing the second adhesive member 5 on the outer upper surface 15 of the base 1 and/or the lower surface 63 of the optical member 6, and a step (S33) of disposing the optical member 6 on the outer upper surface 15 of the base 1 via the second adhesive member 5.

### Fourth Embodiment

### Configuration of Light-Emitting Device According to Fourth Embodiment

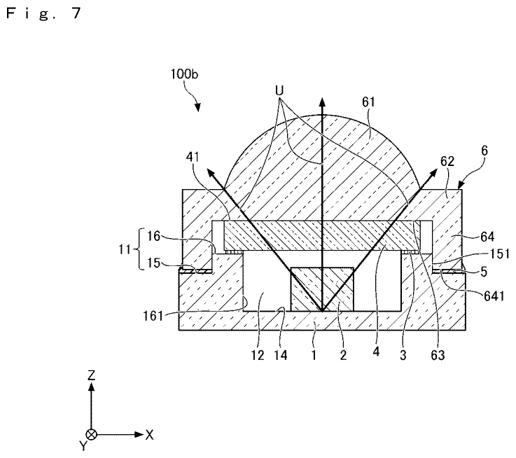

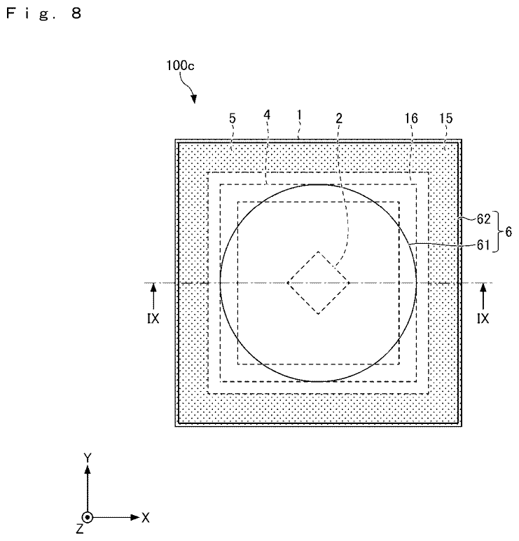

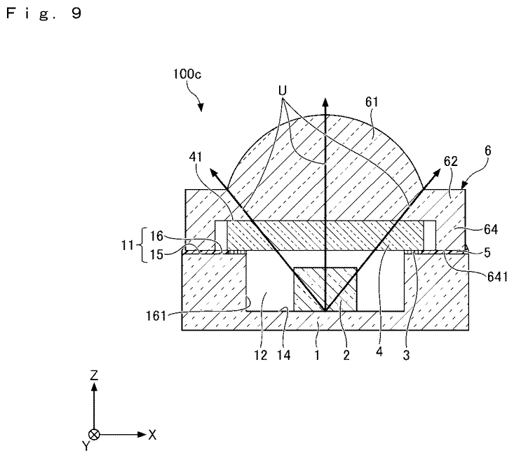

A configuration of a light-emitting device according to a fourth embodiment is described with reference to FIGS. 8 and 9. FIG. 8 is a schematic top view illustrating a light-emitting device 100c according to the fourth embodiment. FIG. 9 is a schematic cross-sectional view taken along line IX-IX in FIG. 8. In the example illustrated in FIG. 8, hatching is applied to the second adhesive member 5 in order to easily distinguish the members. In the example illustrated in FIG. 9, a part of the ultraviolet light U emitted from the light-emitting element 2 is indicated by an arrow.

In the light-emitting device 100c according to the fourth embodiment, the upper surface 11 of the base 1 includes an outer upper surface 15 and an inner upper surface 16 located inward of the outer upper surface 15 in a top view. The inner upper surface 16 is flush with the outer upper surface 15. The light-transmissive member 4 is disposed on the inner upper surface 16 via the first adhesive member 3. The optical member 6 is disposed on the outer upper surface 15 via the second adhesive member 5. The light-emitting device 100c according to the fourth embodiment is different from the light-emitting device 100 according to the first embodiment mainly in the above points. The outer upper surface 15 corresponds to a region where the second adhesive member 5 is disposed on the upper surface 11 of the base 1, and the inner upper surface 16 corresponds to a region where the second adhesive member 5 is not disposed on the upper surface 11 of the base 1. The term “height” as used herein refers to the distance in the +Z direction from the bottom surface 14 of the recessed portion 12 of the base 1.

In the example illustrated in FIG. 9, the optical member 6 includes a leg portion 64 connected to the flange portion 62, below the flange portion 62. For the optical member 6, the lower surface 641 of the leg portion 64 is disposed on the outer upper surface 15 via the second adhesive member 5.

In the light-emitting device 100c, by disposing the second adhesive member 5 on the outer upper surface 15, the second adhesive member 5 can be disposed in a region close to the outer end portion on the upper surface 11 in a top view. Thus, in the light-emitting device 100c, the ultraviolet light U with which the second adhesive member 5 is irradiated can be reduced, and thus the deterioration of the second adhesive member 5 can be reduced.

In the light-emitting device 100c, the second adhesive member 5 is in contact with the first adhesive member 3. This can increase the adhesive strength with which the light-transmissive member 4 is bonded to the base 1 via the first adhesive member 3. However, the second adhesive member 5 may be spaced apart from the first adhesive member 3.

### Method of Manufacturing Light-Emitting Device 100c

The method of manufacturing the light-emitting device 100c includes, for example, a step (S10) of disposing the light-emitting element 2 on the base 1, a step (S41) of disposing the light-transmissive member 4 on the inner upper surface 16 of the base 1 via the first adhesive member 3, a step (S42) of disposing the second adhesive member 5 on the outer upper surface 15 of the base 1, and a step (S43) of disposing the optical member 6 on the outer upper surface 15 of the base 1 and/or the lower surface 63 of the optical member 6 via the second adhesive member 5.

### MODIFIED EXAMPLE

### First Modified Example

A configuration of a light-emitting device according to a first modified example is described with reference to FIG. 10. FIG. 10 is a schematic cross-sectional view illustrating a light-emitting device 100d according to the first modified example. FIG. 10 illustrates a cross-section of the light-emitting device 100d corresponding to the line II-II in FIG. 1.

The light-emitting device 100d is different from the light-emitting device 100 according to the first embodiment in that the light-emitting device 100d includes a reflection reducing film 7 disposed on each of the lens portion 61, an upper surface 621 of the flange portion 62, and a lateral surface 622 of the flange portion 62.

The light-emitting device 100d includes the reflection reducing film 7, thereby reducing stray light derived from, of the ultraviolet light emitted from the light-emitting element 2, a portion reflected by each of the lens portion 61 and the upper surface 621 and the lateral surface 622 of the flange portion 62.

### Second Modified Example

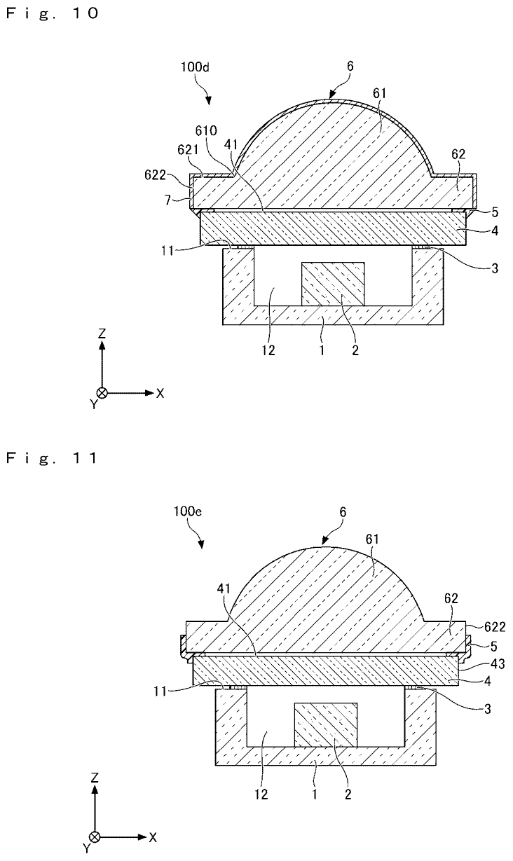

A configuration of a light-emitting device according to a second modified example is described with reference to FIG. 11. FIG. 11 is a schematic cross-sectional view illustrating a light-emitting device 100e according to the second modified example. FIG. 11 illustrates a cross-section of the light-emitting device 100e corresponding to the line II-II in FIG. 1.

The light-emitting device 100e is different from the light-emitting device 100 according to the first embodiment in that the second adhesive member 5 is disposed on the lateral surface 622 of the flange portion 62. In the light-emitting device 100e, the second adhesive member 5 is disposed between the optical member 6 and the light-transmissive member 4, on the lateral surface 622 of the flange portion 62, and on the lateral surface 43 of the light-transmissive member 4. Thus, the adhesive strength of the second adhesive member 5 that bonds the optical member 6 and the light-transmissive member 4 can be increased. The second adhesive member 5 need not be disposed on the lateral surface 43 of the light-transmissive member but may be disposed between the optical member 6 and the light-transmissive member 4 and on the lateral surface 622 of the flange portion 62.

### Third Modified Example

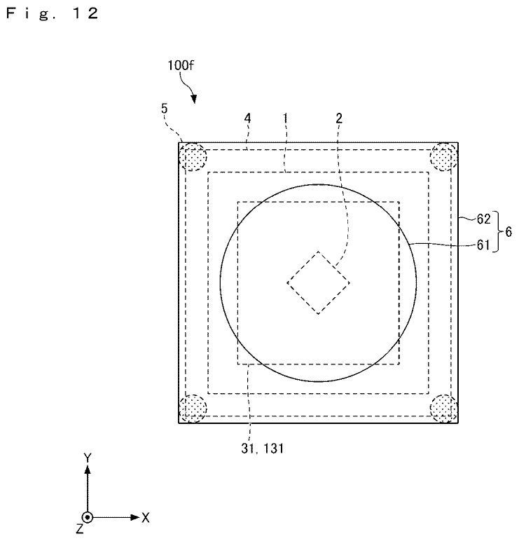

A configuration of a light-emitting device according to a third modified example is described with reference to FIG. 12. FIG. 12 is a schematic top view illustrating a light-emitting device 100f according to the third modified example. In the example illustrated in FIG. 12, hatching is applied to the second adhesive member 5 in order to easily distinguish the members.

The light-emitting device 100f is different from the light-emitting device 100 according to the first embodiment in that the second adhesive member 5 is discretely disposed around the entire periphery of the annular flange portion 62 of the optical member 6 in a top view. In the light-emitting device 100f, the second adhesive member 5 is disposed between the light-transmissive member 4 and the optical member 6 at each of the four corners of the flange portion 62.

Since the second adhesive member 5 is discretely disposed around the entire periphery of the annular flange portion 62 of the optical member 6, the influence of a decrease in the light extraction efficiency of the light-emitting device due to discoloration of the second adhesive member 5 can be reduced as compared with when the second adhesive member 5 is continuously disposed around the entire periphery of the annular flange portion 62 illustrated in FIG. 1. On the other hand, when the second adhesive member 5 is continuously disposed around the entire periphery of the annular flange portion 62 illustrated in FIG. 1, the adhesive strength of the second adhesive member 5 that bonds the optical member 6 and the light-transmissive member 4 can be increased as compared with when the second adhesive member 5 is discretely disposed.

### Fourth Modified Example

A configuration of a light-emitting device according to a fourth modified example is described with reference to FIG. 13. FIG. 13 is a schematic cross-sectional view illustrating a light-emitting device 100g according to the fourth modified example.

The light-emitting device 100g according to the fourth modified example is different from the light-emitting device 100 according to the first embodiment in that the upper surface 41 of the light-transmissive member 4 and the lower surface 42 of the optical member 6 are in contact with each other and the second adhesive member 5 is disposed between the lateral surface 43 of the light-transmissive member 4 and the lower surface 42 of the optical member 6.

### Fifth Embodiment

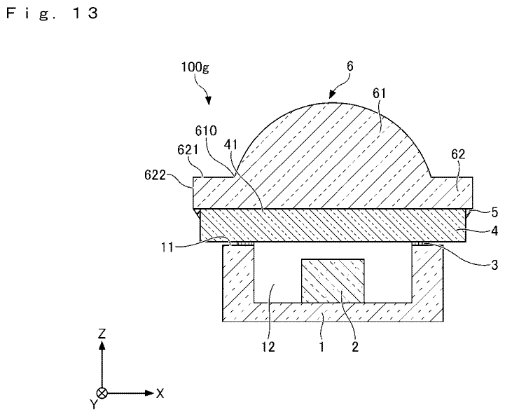

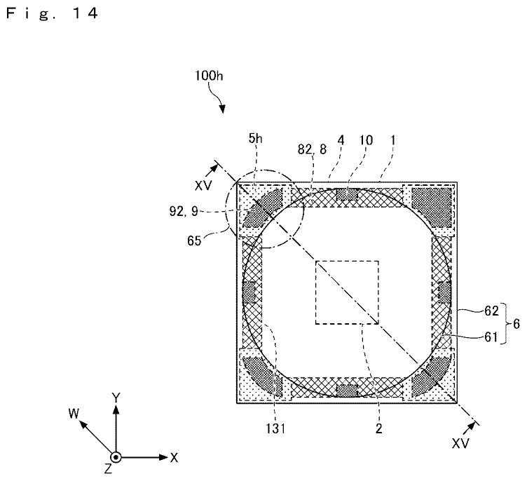

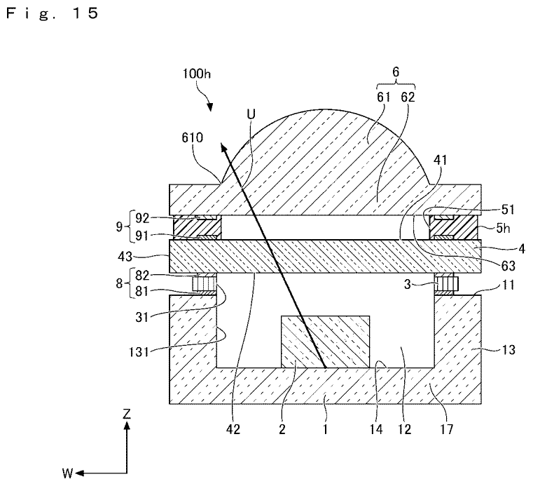

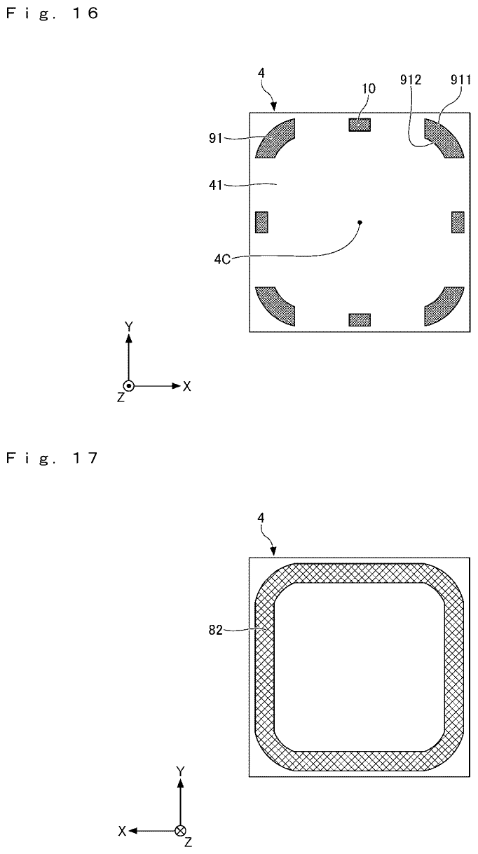

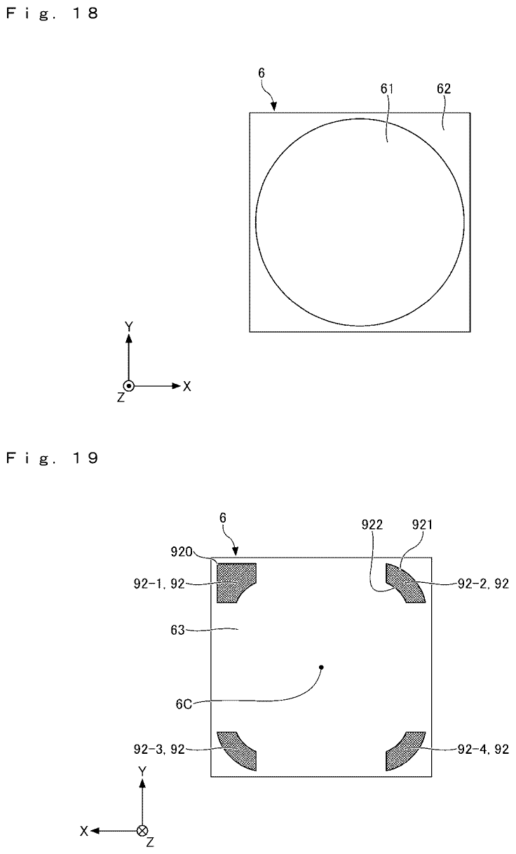

A light-emitting device according to a fifth embodiment will be described with reference to FIGS. 14 to 19. FIG. 14 is a schematic top view illustrating an overall configuration of a light-emitting device 100h according to the fifth embodiment. FIG. 15 is a schematic cross-sectional view taken along line XV-XV in FIG. 14. FIG. 16 is a schematic top view of the light-transmissive member 4 in the light-emitting device 100h. FIG. 17 is a schematic bottom view of the light-transmissive member 4 in the light-emitting device 100h. FIG. 18 is a schematic top view of the optical member 6 in the light-emitting device 100h. FIG. 19 is a schematic bottom view of the optical member 6 in the light-emitting device 100h.

The light-emitting device 100h according to the present embodiment is different from the light-emitting device 100 according to the first embodiment in that the optical member 6 is disposed on the upper surface 41 of the light-transmissive member 4 via a metal adhesive member 5h containing a metal sintered compact instead of the second adhesive member.

In the example illustrated in FIG. 14, each of the base 1, the light-emitting element 2, the light-transmissive member 4, and the optical member 6 has a rectangular shape in a top view. The shapes of the base 1, the light-emitting element 2, the light-transmissive member 4, and the optical member 6 in a top view may be other shapes such as a circular shape, an elliptical shape, and a polygonal shape, and may be different from one another.

In the example illustrated in FIG. 15, at least one metal film 8 is in contact with the first adhesive member 3, and each of the at least one metal film 8 is disposed on a corresponding one of the base 1 and the light-transmissive member 4. The at least one metal film 8 includes a first metal film 81 and a second metal film 82. The first metal film 81 is disposed on the upper surface 11 of the base 1 and is bonded to the first adhesive member 3. The second metal film 82 is disposed on the lower surface 42 of the light-transmissive member 4 and is bonded to the first adhesive member 3.

Further, at least one metal film 9 is in contact with the metal adhesive member 5h, and each of the at least one metal film 9 is disposed on a corresponding one of the optical member 6 and the light-transmissive member 4. The at least one metal film 9 includes a third metal film 91 and a fourth metal film 92. The third metal film 91 is disposed on the upper surface 41 of the light-transmissive member 4 and is bonded to the metal adhesive member 5h. The fourth metal film 92 is disposed on the lower surface 63 of the optical member 6 and is bonded to the metal adhesive member 5h. The at least one metal film 9 is not limited to include both a metal film 9 disposed on the optical member 6 and a metal film 9 the light-transmissive member 4, and may include at least one of a metal film 9 disposed on the optical member 6 or a metal film 9 disposed on the light-transmissive member 4.

### Material of Metal Adhesive Member 5h

When a metal sintered compact is used as the metal adhesive member 5h, the members are bonded to each other by heating a metal paste including particles of metal at a temperature lower than the melting point of the metal and sintering the metal paste to form a sintered compact. The metal paste is disposed on the third metal film 91 disposed on the upper surface of the light-transmissive member 4. The metal paste is disposed on the third metal film 91 by, for example, applying. The metal paste includes, for example, at least one kind of particles selected from the group consisting of silver particles, copper particles, and gold particles. From the viewpoint of light reflectivity of the metal adhesive member 5h with respect to the ultraviolet light U from the light-emitting element 2, silver particles are preferably used as the raw material of the metal sintered compact.

The melting point of the metal adhesive member 5h is lower than the melting point of the first adhesive member 3. For example, in the manufacturing process of the light-emitting device 100h, the light-transmissive member 4 is bonded onto the base 1 by using the first adhesive member 3, and then the optical member 6 is bonded to the light-transmissive member 4 by using the metal adhesive member 5h. If the melting point of the metal adhesive member 5h is equal to or higher than the melting point of the first adhesive member 3, the first adhesive member 3 may be melted when the metal adhesive member 5h is melted to bond the optical member 6. If the first adhesive member 3 is melted, the light-transmissive member 4 may be detached off from the base 1. In the present embodiment, with the melting point of the metal adhesive member 5h lower than the melting point of the first adhesive member 3, the first adhesive member 3 is not melted even when the metal adhesive member 5h is melted for disposing the optical member 6 in the manufacturing process of the light-emitting device 100h. This can reduce the likelihood that the light-transmissive member 4 is detached off from the base 1 due to melting of the first adhesive member 3.

The Young's modulus of the metal adhesive member 5h is preferably lower than the Young's modulus of the first adhesive member 3. For example, when the optical member 6 is made of glass, the optical member 6 may crack when the optical member 6 is bonded onto the light-transmissive member 4 via the metal adhesive member 5h. With the Young's modulus of the metal adhesive member 5h lower than the Young's modulus of the first adhesive member 3, the distortion of the optical member 6 at the time of bonding can be absorbed by the metal adhesive member having low rigidity. As a result, the likelihood of cracking in the optical member 6 is reduced.

### Position of Metal Adhesive Member 5h

In the example illustrated in FIG. 14, the entire metal adhesive member 5h is disposed outward of the lens portion 61 of the optical member 6 in a top view. The metal adhesive member 5h is intermittently disposed in the circumferential direction on the outer peripheral side of the optical member 6. The metal adhesive member 5h is disposed at each of the four corner portions 65 of the optical member 6. The corner portion refers to a region including an intersection point of two sides and the vicinity of the intersection.

When the entirety of the metal adhesive member 5h is located outward of the lens portion 61 in a top view, the ultraviolet light U with which the metal adhesive member 5h is irradiated can be reduced, and thus the deterioration of the metal adhesive member 5h can be reduced. On the other hand, when the metal adhesive member 5h contains a metal sintered compact, the metal adhesive member 5h is less likely to be photodegraded by irradiation with the ultraviolet light U than when the metal adhesive member 5h is made of a resin. Therefore, in the light-emitting device 100h, when the metal adhesive member 5h contains a metal sintered compact, a part of the metal adhesive member 5h can be located inward of the outer end portion 610 of the lens portion 61 in a top view.

The metal adhesive member 5h may or may not protrude outward of the fourth metal film 92 in a top view. In the example illustrated in FIG. 14, the metal adhesive member 5h protrudes outward of the fourth metal film 92 in a top view. When the metal adhesive member 5h protrudes outward of the fourth metal film 92 in a top view, the metal adhesive member 5h covers the lateral surface(es) of the fourth metal film 92. Thus, the contact area between the metal adhesive member 5h and the fourth metal film 92 increases, resulting in an increase in the adhesive strength between the optical member 6 and the light-transmissive member 4.

In order to bond the light-transmissive member 4 and the optical member 6 to each other, the light-emitting device 100h may or may not include the second adhesive member 5 disposed on the outer side of the metal adhesive member 5h, between the light-transmissive member 4 and the optical member 6. When the second adhesive member 5 is disposed outside the metal adhesive member 5h, the metal adhesive member 5h allows for improving the light resistance to the ultraviolet light U from light-emitting element, and the second adhesive member 5 allows for improving sulfur resistance to sulfide present in the outside air. When the light-emitting device 100h includes the metal adhesive member 5h and the second adhesive member 5, the metal adhesive member 5h and the second adhesive member 5 are obtained by, for example, disposing a metal paste and an uncured resin on the upper surface of the light-transmissive member and simultaneously heating the metal paste and the uncured resin.

### Material of Metal Film 9

As a material of the metal film 9, gold or the like can be used.

### Position of Metal Film 9

In the example illustrated in FIG. 14, the metal films 9 are located outward of the lens portion 61 in a top view. Further, the metal films 9 are intermittently disposed in the circumferential direction on the outer peripheral side of each of the optical member 6 and the light-transmissive member 4. Specifically, the metal films 9 are disposed at the four corner portions 65 of the optical member 6 and the four corner portions 65 of the light-transmissive member 4. Corner portions of the optical member 6 and corner portions of the light-transmissive member 4 overlap each other in a top view, and the corner portions 65 represent the corner portions of the optical member 6 and the corner portions of the light-transmissive member 4.

The fourth metal film 92 of the metal film 9 may overlap the entirety of the third metal film 91 or a part of the third metal film 91 in a top view. The metal film 9 may overlap the entirety of the metal film 8 or a part of the metal films 8 in a top view.

The at least one metal film 9 is located outward of the lens portion 61 in a top view. Thus, the ultraviolet light U traveling from the light-emitting element 2 to the lens portion 61 is less likely to impinge on the metal film 9, thereby inhibiting a decrease in the light extraction efficiency of the ultraviolet light U emitted from the lens portion 61 to the outside.

When metal films 9 are intermittently disposed in the circumferential direction on the outer peripheral side of each of the optical member 6 and the light-transmissive member 4, the area of the region where the metal film 9 is disposed is smaller in each of the optical member 6 and the light-transmissive member 4 than when a metal film 9 being continuous in the circumferential direction is disposed on the outer peripheral side of each of the optical member 6 and the light-transmissive member 4. Thus, of the ultraviolet light U emitted from the light-emitting element 2, a portion incident on the metal films 9 is reduced, so that the light absorption by the metal film 9 is reduced and the light extraction efficiency of the light-emitting device 100h is improved. The metal films 9 are not limited to being intermittently disposed in the circumferential direction on the outer peripheral side of each of the optical member 6 and the light-transmissive member 4, and may be intermittently disposed in the circumferential direction on the outer peripheral side of either the optical member 6 or the light-transmissive member 4.

### Shape of Metal Film 9

In the example illustrated in FIG. 16, shapes of the third metal films 91 disposed at the four corners of the upper surface 41 of the light-transmissive member 4 are point-symmetrical with respect to a center 4C of the light-transmissive member 4 in a top view.

In the example illustrated in FIG. 19, the fourth metal films 92 disposed at the four corners of the lower surface 63 of the optical member 6 includes a fourth metal film 92-1, a fourth metal film 92-2, a fourth metal film 92-3, and a fourth metal film 92-4.

In a top view, the fourth metal film 92-2 and the fourth metal film 92-3 are point-symmetrical with respect to a center 6C of the optical member 6. The shape of the fourth metal film 92-2 and the shape of the fourth metal film 92-4 are symmetrical with respect to a straight line parallel to the X direction passing through the center of the optical member 6. The fourth metal film 92-1 has a shape that is not point-symmetrical to the fourth metal film 92-4 in a top view.

In a top view, the fourth metal film 92-1 includes a curved inner edge and an outer edge having a right-angled portion 920 being an intersection point where two sides intersect at a right angle. On the other hand, each of the fourth metal film 92-2, the fourth metal film 92-3, and the fourth metal film 92-4 includes a curved inner edge 922 and a curved outer edge 921.

In the light-emitting device 100h, the fourth metal film 92-1 can be used as an identification mark. For example, in the light-emitting device 100h, the fourth metal film 92-1 can be used as a cathode mark. However, shapes of all of the fourth metal films 92 disposed at the four corners may be point-symmetrical with respect to the center 6C of the optical member 6 in a top view.

In the example illustrated in FIG. 16, the curved surfaces of the outer edge 911 and the inner edge 912 of each of the four third metal films 91 have the same curvature in a top view. The curvature of the curved surface can be the same as the curvature of the curved surface of the outer end portion of the lens portion 61. In the example illustrated in FIG. 19, the curved surfaces of an inner edge 922 of the fourth metal film 92-1 and the outer and inner edges 921 and 922 of each of the fourth metal film 92-2, the fourth metal film 92-3, and the fourth metal film 92-4 have the same curvature in a top view. The curvature of these curved surfaces can be the same as the curvature of the curved surface of the outer end portion of the lens portion 61.

In the example illustrated in FIG. 16, the third metal film 91 is disposed at each of the four corner portions 65 on the upper surface 41 of the light-transmissive member 4, and the metal film 10 is further disposed between adjacent ones of the corner portions. The metal film 10 is made of, for example, the same material as that of the third metal film 91. The metal film 10 can be used as a mark for alignment of the optical member 6 when the optical member 6 is disposed on the light-transmissive member 4. By using the metal film 10 as an alignment mark, the alignment accuracy of the optical member 6 is improved. The metal film 10 may or may not be in contact with the metal adhesive member 5h.

Preferred embodiments have been described above in detail. However, the present disclosure is not limited to the above-described embodiments, and various modifications and substitutions can be made to the above-described embodiments without departing from the scope described in the claims. The above-described embodiments and modified examples can be implemented in combination with each other.

The ordinal numbers, quantity, and the like used in the description of the embodiments are all exemplified to specifically describe the technology of the present disclosure, and the present disclosure is not limited to the numbers exemplified. In addition, the connection relationship between the components is exemplified to specifically describe the technique of the present disclosure, and the connection relationship for implementing the function of the present disclosure is not limited thereto.

In a light-emitting device of the present disclosure, the deterioration of an adhesive member disposed between an optical member and a light-transmissive member can be reduced; thus, the light-emitting device can be suitably used in applications such as printing and exposure in which an object is irradiated with ultraviolet light in order to cure the object. However, the light-emitting device of the present disclosure is not limited to these applications.

What is claimed is:

1. A light-emitting device, comprising:
a base having an upper surface and a recessed portion on a side of the upper surface;
a light-emitting element disposed in the recessed portion and configured to emit ultraviolet light;
a light-transmissive member disposed on the upper surface of the base via a first adhesive member containing no resin; and
an optical member disposed on either a region of the upper surface of the base where the light-transmissive member is not disposed or an upper surface of the light-transmissive member via a second adhesive member containing a resin, the optical member comprising a lens portion and a flange portion, wherein
the second adhesive member is located outward of the lens portion in a top view.

2. The light-emitting device according to claim 1, wherein each of a width of the light-transmissive member and a width of the optical member is wider than a width of the base in a cross-sectional view.

3. The light-emitting device according to claim 1, wherein a width of the light-transmissive member is narrower than a width of the optical member in a cross-sectional view.

4. The light-emitting device according to claim 1, wherein
the upper surface of the base comprises an outer upper surface and an inner upper surface located inward of the outer upper surface in the top view,
the inner upper surface is located below the outer upper surface,
the light-transmissive member is disposed on the inner upper surface via the first adhesive member, and
the optical member is disposed on the outer upper surface via the second adhesive member.

5. The light-emitting device according to claim 1, wherein
the upper surface of the base comprises an outer upper surface and an inner upper surface located inward of the outer upper surface in the top view,
the inner upper surface is located above the outer upper surface,
the light-transmissive member is disposed on the inner upper surface via the first adhesive member, and
the optical member is disposed on the outer upper surface via the second adhesive member.

6. The light-emitting device according to claim 1, wherein
the upper surface of the base comprises an outer upper surface and an inner upper surface located inward of the outer upper surface in the top view,
the inner upper surface is flush with the outer upper surface,
the light-transmissive member is disposed on the inner upper surface via the first adhesive member, and
the optical member is disposed on the outer upper surface via the second adhesive member.

7. The light-emitting device according to claim 4, wherein the light-transmissive member and the optical member are in contact with each other.

8. The light-emitting device according to claim 4, wherein the light-transmissive member and the optical member are spaced apart from each other.

9. The light-emitting device according to claim 4, wherein a lateral surface of the light-transmissive member is spaced apart from a lateral surface of the base connecting the outer upper surface and the inner upper surface of the base.

10. The light-emitting device according to claim 4, wherein the lens portion is disposed inward of the outer upper surface in the top view.

11. The light-emitting device according to claim 4, wherein an inner end portion of the second adhesive member is spaced apart from an inner end portion of the outer upper surface of the base in the top view.

12. The light-emitting device according to claim 1, further comprising a reflection reducing film disposed on each of the lens portion, an upper surface of the flange portion, and a lateral surface of the flange portion.

13. The light-emitting device according to claim 1, wherein the second adhesive member is disposed between the optical member and the light-transmissive member and on a lateral surface of the flange portion.

14. A light-emitting device, comprising:
a base having an upper surface and a recessed portion on a side of the upper surface;
a light-emitting element disposed in the recessed portion and configured to emit ultraviolet light;
a light-transmissive member disposed on the upper surface of the base via a first adhesive member containing no resin; and
an optical member disposed on an upper surface of the light-transmissive member via a metal adhesive member containing a metal sintered compact, the optical member comprising a lens portion and a flange portion, wherein
at least a part of the metal adhesive member is disposed outward of the lens portion in a top view.

15. The light-emitting device according to claim 14, wherein a whole of the metal adhesive member is disposed outward of the lens portion in the top view.

16. The light-emitting device according to claim 14, further comprising at least one metal film in contact with the metal adhesive member, the at least one metal film comprising at least one of a metal film disposed on the optical member or a metal film disposed on the light-transmissive member, wherein
the at least one metal film is located outward of the lens portion in the top view.

17. The light-emitting device according to claim 16, wherein the at least one metal film is intermittently disposed around an entire periphery of at least one of the optical member or the light-transmissive member.

18. The light-emitting device according to claim 17, wherein
the optical member and the light-transmissive member each have a rectangular shape in the top view, and
the at least one metal film includes at least one of a metal film disposed at a corner portion of the optical member or a metal film disposed at a corner portion of the light-transmissive member.
